(19) United States
(12) Patent Application Publication
(10) Pub. No.: US 2017/0149198 A1
(43) Pub. Date: May 25, 2017

(54) LIGHT SOURCE SYSTEM, BEAM TRANSMISSION SYSTEM, AND EXPOSURE APPARATUS

(71) Applicant: GIGAPHOTON INC., Tochigi (JP)

(72) Inventors: Osamu WAKABAYASHI, Tochigi (JP); Shinji OKAZAKI, Tochigi (JP); Akiyoshi SUZUKI, Tochigi (JP)

(73) Assignee: GIGAPHOTON INC., Tochigi (JP)

(21) Appl. No.: 15/426,155

(22) Filed: Feb. 7, 2017

Related U.S. Application Data
(63) Continuation of application No. PCT/JP2014/076119, filed on Sep. 30, 2014.

(51) Int. Cl. H01S 3/08; H01S 3/11; G03F 7/20; H01S 3/09

(52) U.S. Cl. CPC H01S 3/08009; H01S 3/0903; H01S 3/11; H01S 3/08059; G03F 7/70025; G02B 17/0621

(57) ABSTRACT

There is provided a light source system that may include a free electron laser apparatus, a light concentrating mirror, and a delaying optical system. The free electron laser apparatus may include an undulator, and may be configured to output a pulsed laser light beam toward an exposure apparatus. The light concentrating mirror may be configured to concentrate the pulsed laser light beam to enter the exposure apparatus. The delaying optical system may be provided in an optical path between the undulator and the light concentrating mirror, and may be configured to delay the pulsed laser light beam to allow an amount of delay of the pulsed laser light beam to be varied depending on a position in a beam cross-section of the pulsed laser light beam.

### CROSS REFERENCE TO RELATED APPLICATIONS

The present application is a continuation application of International Application No. PCT/JP2014/076119 filed on Sep. 30, 2014. The content of the application is incorporated herein by reference in its entirety.

### BACKGROUND

1. Technical Field

The present disclosure relates to a light source system that outputs a pulsed laser light beam from a free electron laser (FEL) apparatus, a beam transmission system that transmits a pulsed laser light beam from a free electron laser apparatus, and an exposure apparatus that is supplied with a pulsed laser light beam from a free electron laser apparatus.

2. Related Art

In recent years, miniaturization of a transfer pattern of an optical lithography in a semiconductor process is drastically progressing with the development in fining of the semiconductor process. In the next generation, microfabrication on the order of 70 nm to 45 nm, and further microfabrication on the order of 32 nm or less are bound to be required. To meet such requirement for the microfabrication on the order of, for example, 32 nm or less, development is anticipated of an exposure apparatus that includes a combination of a reduced projection reflective optics and an extreme ultraviolet light generating apparatus that generates extreme ultraviolet (EUV) light with a wavelength of about 13 nm. For example, reference is made in U.S. Patent Application Publication No. 2013/0148203, U.S. Pat. No. 7,050,237, and International Publication No. WO 2013/024316.

As the EUV light generating apparatus, there have been proposed three kinds of apparatuses, a laser produced plasma (LPP) apparatus using plasma generated by application of a laser beam to a target substance, a discharge produced plasma (DPP) apparatus using plasma generated by discharge, and a free electron laser apparatus using electrons outputted from an electron accelerator.

### SUMMARY

A light source system according to one aspect of the present disclosure may include a free electron laser apparatus, a light concentrating mirror, and a delaying optical system. The free electron laser apparatus may include an undulator, and may be configured to output a pulsed laser light beam toward an exposure apparatus. The light concentrating mirror may be configured to concentrate the pulsed laser light beam to enter the exposure apparatus. The delaying optical system may be provided in an optical path between the undulator and the light concentrating mirror, and may be configured to delay the pulsed laser light beam to allow an amount of delay of the pulsed laser light beam to be varied depending on a position in a beam cross-section of the pulsed laser light beam.

A beam transmission system according to one aspect of the present disclosure may include a delaying optical system. The delaying optical system may be provided in an optical path between an exposure apparatus and a free electron laser apparatus configured to output a pulsed laser light beam toward the exposure apparatus, and may be configured to delay the pulsed laser light beam to allow an amount of delay of the pulsed laser light beam to be varied depending on a position in a beam cross-section of the pulsed laser light beam, and thereafter concentrate the pulsed laser light beam.

An exposure unit according to one aspect of the present disclosure may include an illumination optical system. The illumination optical system may be configured to generate illumination light on the basis of a pulsed laser light beam provided from a free electron laser apparatus, and may include a delaying optical system. The delaying optical system may be configured to delay the pulsed laser light beam to allow an amount of delay of the pulsed laser light beam to be varied depending on a position in a beam cross-section of the pulsed laser light beam.

### BRIEF DESCRIPTION OF THE DRAWINGS

Some example embodiments of the present disclosure are described below as mere examples with reference to the accompanying drawings.

FIG. 1 schematically illustrates a configuration example of a EUV light source system including a free electron laser apparatus.

FIG. 2 schematically illustrates a configuration example of a EUV light source system according to a first embodiment.

FIG. 3 schematically illustrates an example of a main-part configuration of the EUV light source system illustrated in FIG. 2.

FIG. 4 schematically illustrates an example of delay time ΔT of a pulsed laser light beam.

FIG. 5 schematically illustrates a first modification example of a shape of each of grooves of a grating.

FIG. 6 schematically illustrates a second modification example of the shape of each of the grooves of the grating.

FIG. 7 schematically illustrates a third modification example of the shape of each of the grooves of the grating.

FIG. 8 schematically illustrates a configuration example of a connection of a plurality of gratings.

FIG. 9 schematically illustrates a modification example in which a position of the grating is changed.

FIG. 10 schematically illustrates an example of a main-part configuration of a EUV light source system according to a second embodiment.

FIG. 11 schematically illustrates an example of a main-part configuration of a EUV light source system according to a third embodiment.

FIG. 12 schematically illustrates an example of a multiple mirror system.

FIG. 13 schematically illustrates a first modification example of a shape of a reflection surface of the multiple mirror system.

FIG. 14 schematically illustrates a second modification example of the shape of the reflection surface of the multiple mirror system.

FIG. 15 schematically illustrates an example of a main-part configuration of a EUV light source system according to a fourth embodiment.

FIG. 16 schematically illustrates a configuration example of a first multiple mirror system.

FIG. 17 schematically illustrates a configuration example of a second multiple mirror system.

FIG. 18 schematically illustrates an exposure apparatus according to a fifth embodiment.

FIG. 19 schematically illustrates another configuration example of the multiple mirror system applied to an illumination optical system.

FIG. 20 schematically illustrates a state of reflection of a light beam by each of mirrors of the multiple mirror system illustrated in FIG. 19.

FIG. 21 schematically illustrates a cross-sectional shape of each of reflection surfaces of the multiple mirror system illustrated in FIG. 19.

### DETAILED DESCRIPTION

### <Contents>

### [1. Overview]

[2. EUV Light Source System Including Free Electron Laser apparatus]

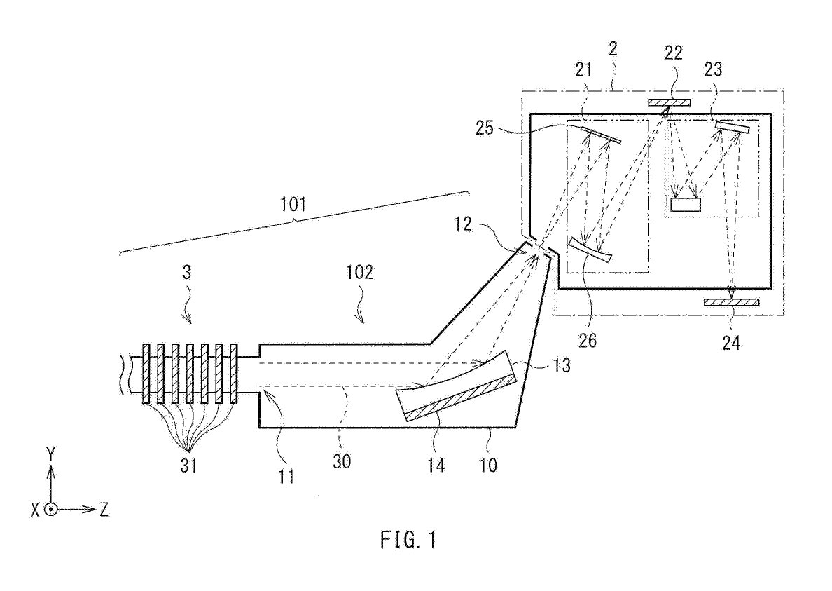

2.1 Configuration (FIG. 1)

2.2 Operation

2.3 Issues

[3. First Embodiment] (EUV light source system including delaying optical system)

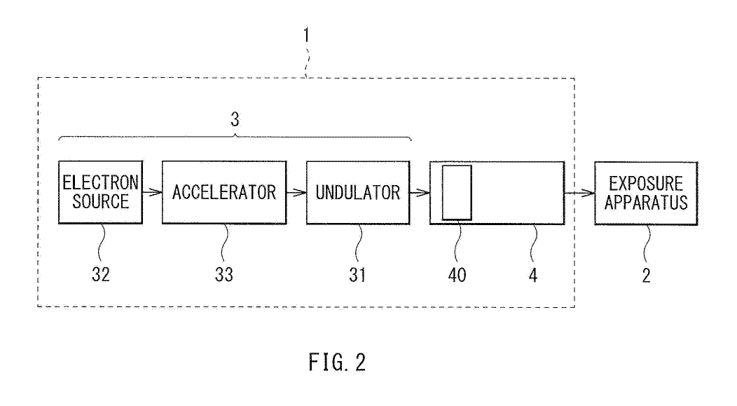

3.1 Configuration (FIGS. 2 to 4)

3.2 Operation

3.3 Effect

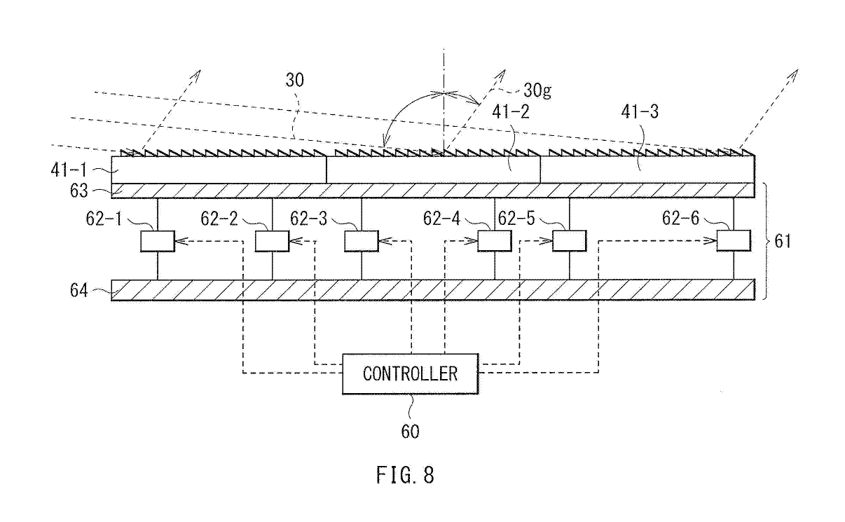

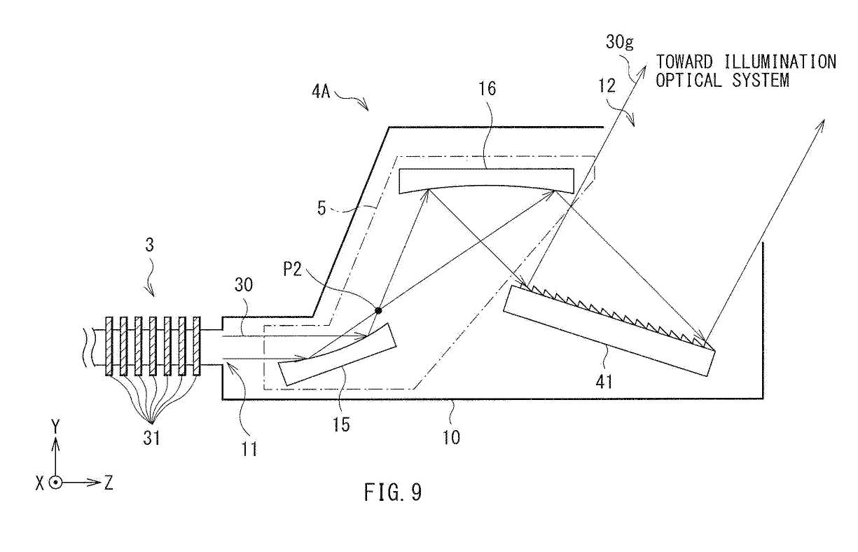

3.4 Modification Examples (FIGS. 5 to 9)
3.4.1 First Modification Example (Modification example of shape of groove of grating) (FIGS. 5 to 7)
3.4.2 Second Modification Example (Connection of a plurality of gratings) (FIG. 8)
3.4.3 Third Modification Example (Modification example in which position of grating is changed) (FIG. 9)
   [4. Second Embodiment] (Embodiment of beam transmission system including two gratings)

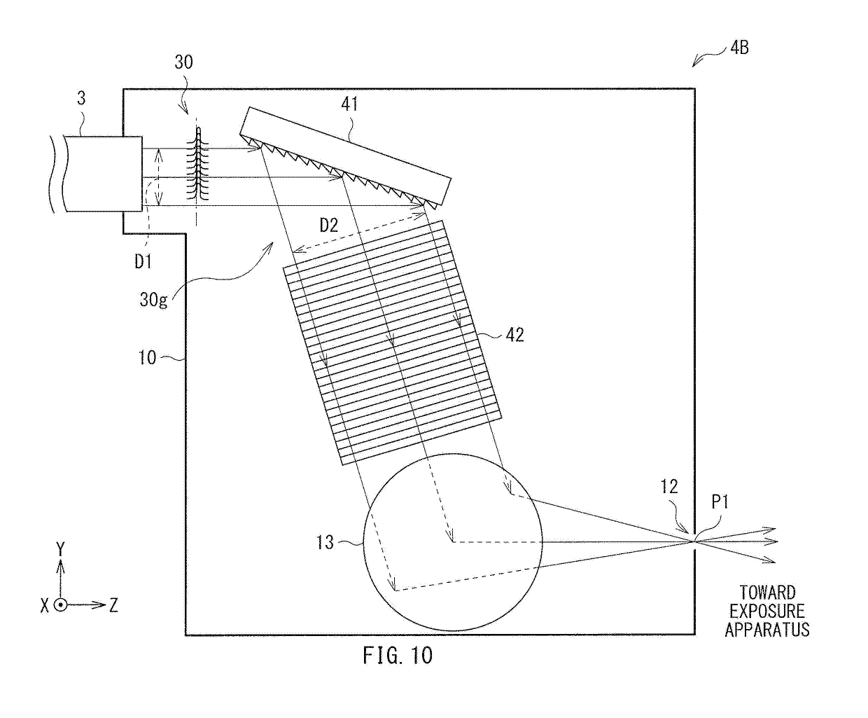

4.1 Configuration (FIG. 10)

4.2 Operation

4.3 Effect

4.4 Modification Example

[5. Third Embodiment] (Embodiment of beam transmission system including multiple mirror system)

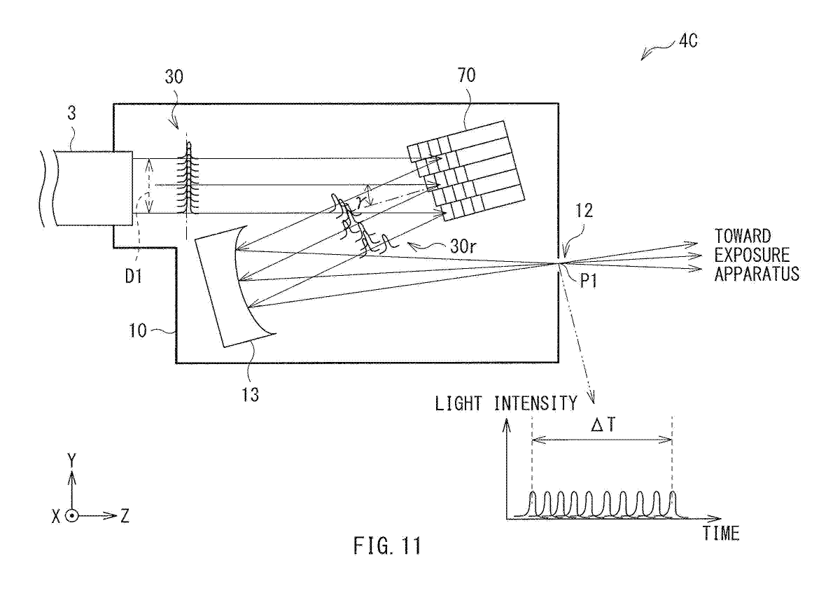

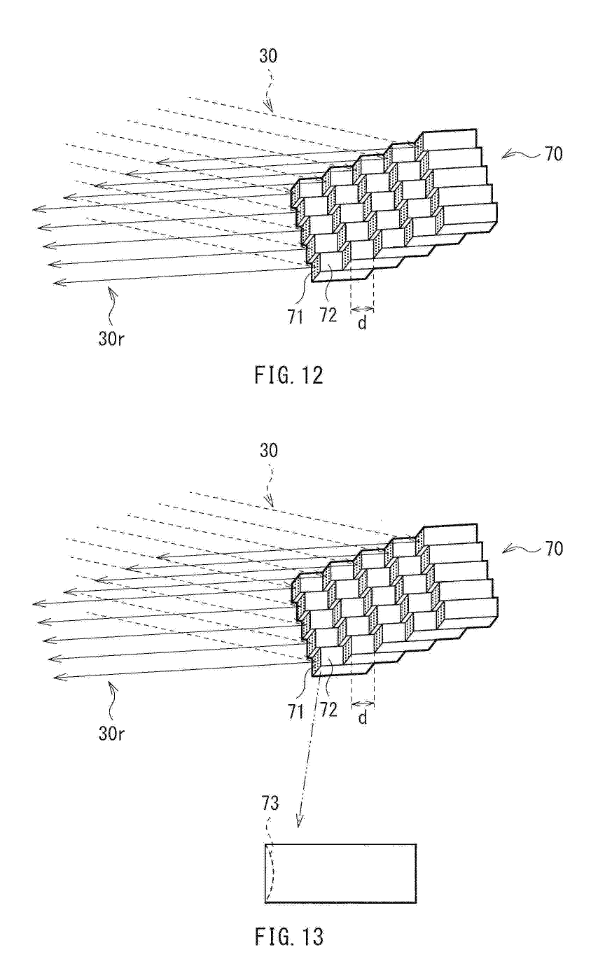

5.1 Configuration (FIGS. 11 and 12)

5.2 Operation

5.3 Effect

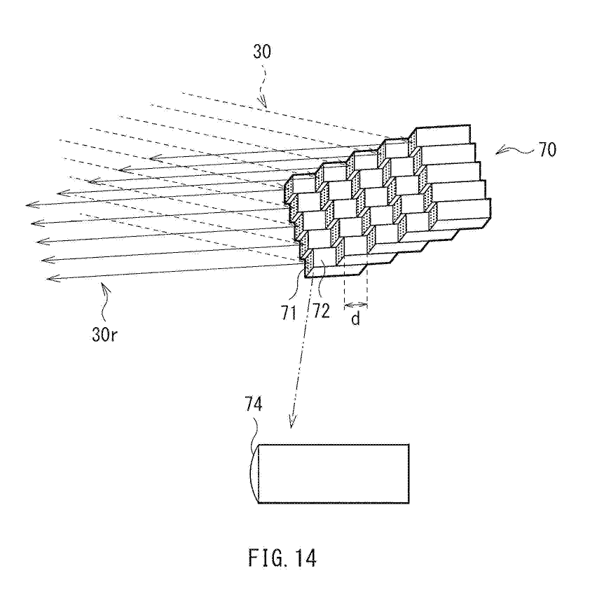

5.4 Modification Examples (FIGS. 13 and 14)

[6. Fourth Embodiment] (Embodiment of beam transmission system including two multiple mirror systems)

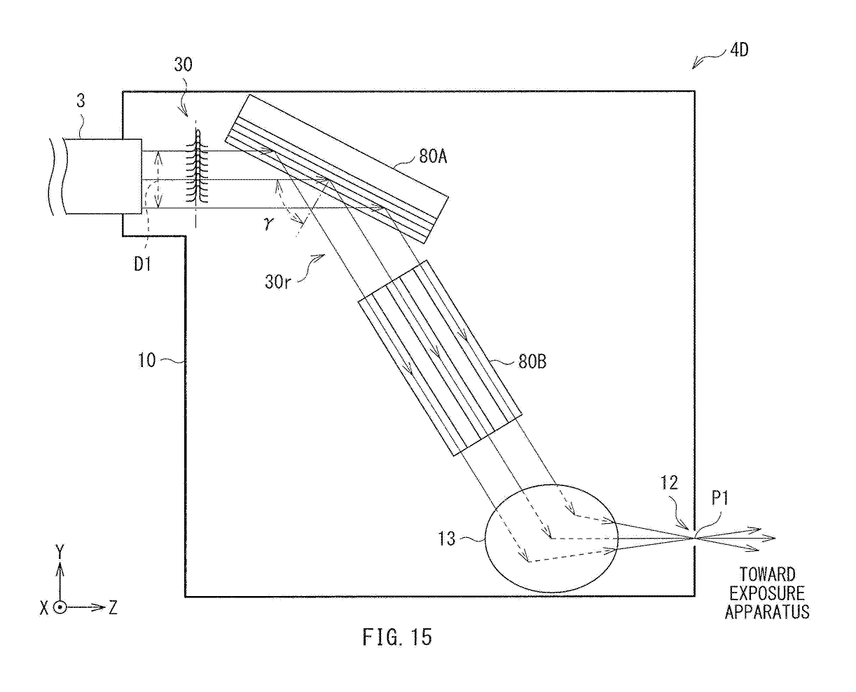

6.1 Configuration (FIGS. 15 to 17)

6.2 Operation

6.3 Effect

6.4 Modification Examples

[7. Fifth Embodiment] (Embodiment of exposure apparatus provided with illumination optical system including multiple mirror system)

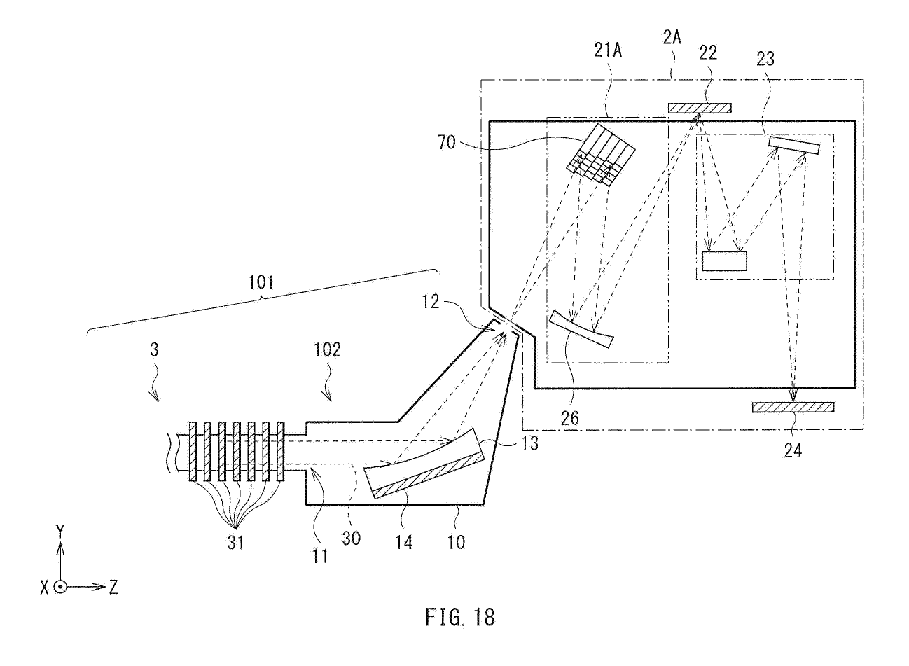

7.1 Configuration (FIG. 18)

7.2 Operation

7.3 Effect

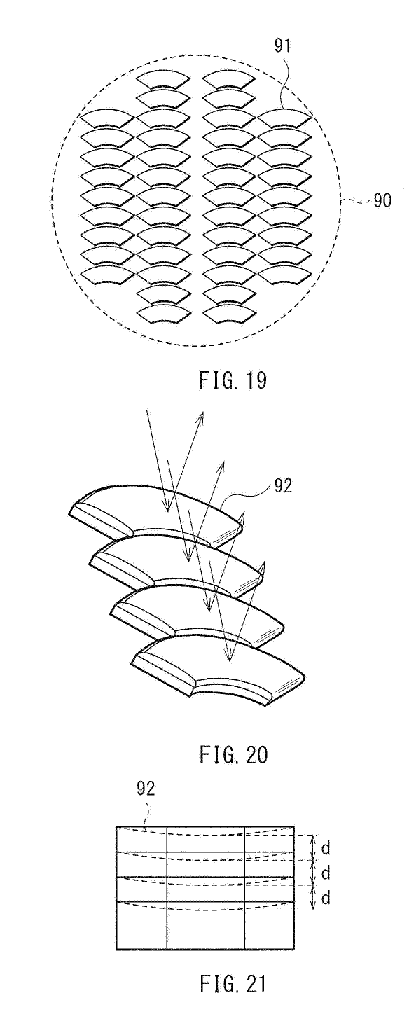

7.4 Modification Examples (FIGS. 19 to 21)

### [8. Et Cetera]

In the following, some example embodiments of the present disclosure are described in detail with reference to the drawings. Example embodiments described below each illustrate one example of the present disclosure and are not intended to limit the contents of the present disclosure. Further, all of the configurations and operations described in each example embodiment are not necessarily essential for the configurations and operations of the present disclosure. Note that like components are denoted by like reference numerals, and redundant description thereof is omitted.

### 1. Overview

The present disclosure relates to a light source system including a delaying optical system, a beam transmission system, and an exposure apparatus. The delaying optical system may delay part of a pulsed laser light beam outputted from a free electron laser apparatus, for example.

### 2. EUV Light Source System Including Free Electron Laser Apparatus

### (2.1 Configuration)

FIG. 1 schematically illustrates a configuration example of a EUV light source system 101 including a free electron laser apparatus 3.

The EUV light source system 101 may include the free electron laser apparatus 3 and a beam transmission system 102. The beam transmission system 102 may transmit a pulsed laser light beam 30 outputted from the free electron laser apparatus 3 toward an exposure apparatus 2.

The free electron laser apparatus 3 may include an undulator 31. The beam transmission system 102 may include a chamber 10, an off-parabolic mirror 13, and a holder 14.

The off-parabolic mirror 13 may be disposed on the holder 14 inside the chamber 10 so that a pulsed laser light beam 30 outputted from the free electron laser apparatus 3 enters the off-parabolic mirror 13 at a predetermined angle and a concentrated reflected light beam of the pulsed laser light beam 30 enters the exposure apparatus 2.

An opening 11 may be formed in the chamber 10. The opening 11 may allow the pulsed laser light beam 30 outputted from the free electron laser apparatus 3 to pass therethrough. The opening 11 of the chamber 10 and an output section of the free electron laser apparatus 3 may be sealed by an O-ring or may be welded together. Further, a through hole 12 may be formed in the chamber 10. The through hole 12 may allow the pulsed laser light beam 30 having been reflected and concentrated by the off-parabolic mirror 13 to pass therethrough. The through hole 12 and an input side of the exposure apparatus 2 may be sealed by an unillustrated sealing member. The chamber 10 may be evacuated close to a vacuum by an unillustrated evacuator in order to suppress attenuation of the pulsed laser light beam 30.

The exposure apparatus 2 may include an illumination optical system 21, a mask 22, a projection optical system 23, and a wafer 24. The illumination optical system 21 may be an optical system configured to generate illumination light with which the mask 35 is illuminated through Koehler illumination. The illumination optical system 21 may include a secondary light source formation-use multiple concave mirror 25 and a condenser optical system 26, for example. The secondary light source formation-use multiple concave mirror 25 may include a plurality of concave mirrors, for example. The condenser optical system 26 may be configured of a concave mirror, for example.

### (2.2 Operation)

In the EUV light source system 101, the pulsed laser light beam 30 outputted from the free electron laser apparatus 3 may enter, at the predetermined angle, the off-parabolic mirror 13 inside the chamber 10 through the opening 11. The off-parabolic mirror 13 may reflect the entering pulsed laser light beam 30 to concentrate the pulsed laser light beam 30 near the through hole 12 at an exit of the chamber 10. The concentrated pulsed laser light beam 30 may enter the exposure apparatus 2 through the through hole 12. The pulsed laser light beam 30 having entered inside of the exposure apparatus 2 may be converted into illumination light by the illumination optical system 21, and a surface of the mask 22 may be uniformly illuminated with the illumination light. The illumination light reflected by the mask 22 may allow the projection optical system 23 to transfer an image of the mask 22 onto the wafer 24.

### (2.3 Issues)

In the free electron laser apparatus 3 that outputs the pulsed laser light beam 30 in a EUV light region, a pulse width is short in a range from about 0.1 ps to about 0.2 ps both inclusive, which may cause the following issues. The pulsed laser light beam 30 outputted from the free electron laser apparatus 3 has a short pulse width and a high peak value. Accordingly, a resist on the wafer 24 may be ablated by the pulsed laser light beam 30, thereby not functioning as a resist. Moreover, for example, an optical film used for various kinds of optical elements in the beam transmission system 102 and the exposure apparatus 2 may be damaged by ablation. For example, a reflection film used for a reflection surface of any of the various kinds of optical elements may be damaged by ablation.

### 3. First Embodiment (EUV Light Source System Including Delaying Optical System)

### 3.1 Configuration

FIG. 2 schematically illustrates a configuration example of a EUV light source system 1 including a delaying optical system 40 according to a first embodiment of the present disclosure. Note that substantially same components as the components of the EUV light source system 101 and the exposure apparatus 2 illustrated in FIG. 1 are denoted by same reference numerals, and redundant description thereof is omitted.

The EUV light source system 1 may include the free electron laser apparatus 3 and a beam transmission system 4. The free electron laser apparatus 3 may output the pulsed laser light beam 30 toward the exposure apparatus 2. The beam transmission system 4 may be provided in an optical path between the free electron laser apparatus 3 and the exposure apparatus 2 and may transmit the pulsed laser light beam 30 to the exposure apparatus 2.

The free electron laser apparatus 3 may include an electron source 32, an accelerator 33, and the undulator 31. The electron source 32 may generate electrons. The accelerator 33 may accelerate the electrons generated by the electron source 32. The undulator 31 may generate, for example, the pulsed laser light beam 30 in the EUV light region from an electron beam accelerated by the accelerator 33 and output the pulsed laser light beam 30.

The beam transmission system 4 may include the delaying optical system 40. The delaying optical system 40 may be provided in an optical path between the free electron laser apparatus 3 and the exposure apparatus 2, and may delay the pulsed laser light beam 30 depending on a beam position. The delaying optical system 40 may be disposed following the undulator 31. The delaying optical system 40 may delay the pulsed laser light beam 30 to allow an amount of delay of the pulsed layer light beam 30 to be varied depending on a position in a beam cross-section in a direction not parallel to the optical path, for example, an oblique direction of the pulsed laser light beam 30. The delaying optical system 40 may spatially divide the pulsed laser light beam 30 into a plurality of segments in the beam cross-section in a direction not parallel to the optical path, for example, the oblique direction to vary the amount of delay for each of the segments.

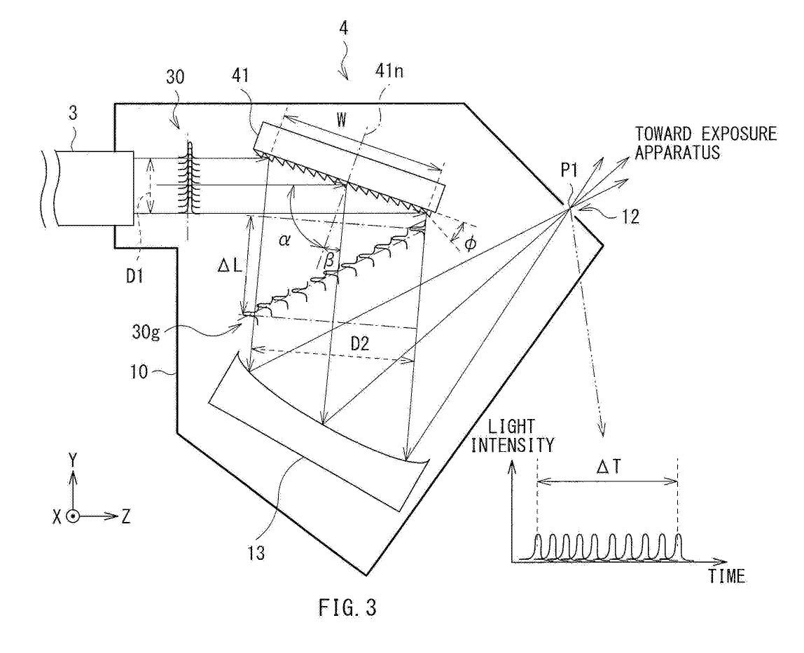

FIG. 3 schematically illustrates a configuration example of the beam transmission system 4 as a main-part configuration of the EUV light source system 1 illustrated in FIG. 2.

The beam transmission system 4 may include a first grading 41 as the delaying optical system 40. The first grating 41 may diffract the pulsed laser light beam 30 to generate a diffracted light beam 30g. The first grating 41 may be provided in an optical path between the free electron laser apparatus 3 and the off-parabolic mirror 13 in the chamber 10. The pulsed laser light beam 30 outputted from the free electron laser apparatus 3 may enter the first grating 41 at a predetermined angle α. The pulsed laser light beam 30 converted into the diffracted light beam 30g by the first grating 41 may enter the exposure apparatus 2 via the off-parabolic mirror 13.

A base material of the first grating 41 may include a metal material having high thermal conductivity, for example, one of Cu, Al, and Si. Moreover, the base material of the first grating 41 may include, for example, a ceramic material such as SiC. A flow path where cooling water flows may be formed in the base material of the first grating 41. The first grating 41 may be a blazed grating provided with grooves disposed at a predetermined interval to increase diffraction efficiency of a predetermined diffracted light beam 30g. A shape of each of the grooves of the first grating 41 may be a triangular wave shape, for example. A surface of the first grating 41 may be coated with a single-layer film of Ru or a multilayer film of Mo and Si to increase reflectivity in the EUV light region.

### 3.2 Operation

In the EUV light source system 1, the free electron laser apparatus 3 may output the pulsed laser light beam 30 with a beam diameter D1, as illustrated in FIG. 3. The pulsed laser light beam 30 with the beam diameter D1 outputted from the free electron laser apparatus 3 may obliquely enter the first grating 41 at the incident angle α and may be diffracted at a diffraction angle β by the first grating 41. Thus, the diffracted light beam 30g having an ellipsoidal shape with a beam width D2 may be generated. At this occasion, the pulsed laser light beam 30 diffracted by the first grating 41 may have an optical path difference depending on a position where the pulsed laser light beam 30 is diffracted by the first grating 41. As a result, pulse timing of the pulsed laser light beam 30 diffracted at the diffraction angle β that is the diffracted light beam 30g may be delayed depending on the position where the pulsed laser light beam 30 is diffracted by the first grating 41. In other words, the pulsed laser light beam 30 with the beam diameter D1 outputted from the free electron laser apparatus 3 may be delayed by the first grating 41 to allow an amount of delay of the pulsed laser light beam 30 to be varied depending on the position in the beam cross-section in a direction not parallel to the optical path, for example, the oblique direction. At this occasion, the pulsed laser light beam 30 may be spatially divided into a plurality of segments in the beam cross-section in accordance with the shape of each of the grooves of the first grating 41 to vary the amount of delay for each of the segments. The pulsed laser light beam 30 that is converted into the diffracted light beam 30g may be concentrated near a predetermined focus point P1 by the off-parabolic mirror 13.

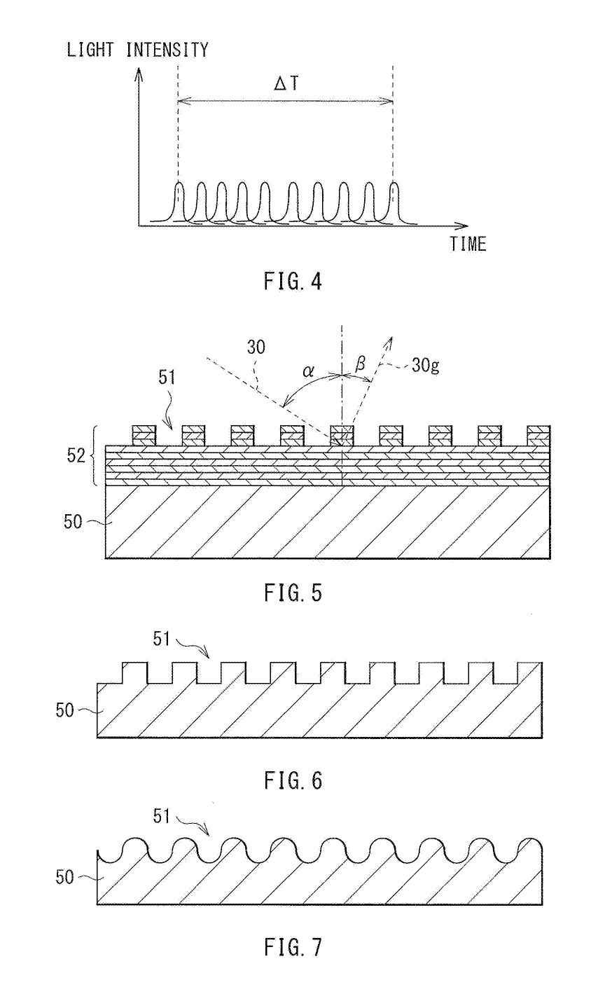

The delay time ΔT of the pulsed laser light beam 30 around the predetermined focus point P1 is schematically illustrated in a right bottom section of FIG. 3 and FIG. 4. In these drawings, a horizontal axis may indicate time, and a vertical axis may indicate light intensity. These drawings schematically illustrate a waveform of each pulse depending on a position in the beam cross-section of the pulsed laser light beam 30. The diffracted light beam 30g generated by the first grating 41 is concentrated near the predetermined focus point P1, as illustrated in these drawings, which may cause a pulse width of the diffracted light beam 30g near the predetermined focus point P1 to increase.

The delay time ΔT of the pulsed laser light beam 30 in FIGS. 3 and 4 may be determined as follows.

The following expression is established for diffraction by the first grading 41. Each of the incident angle α and the diffraction angle β may be an angle with respect to a normal 41n to a grating surface of the first grating 41, as illustrated in FIG. 3.

mλ=a(sin α−sin β) (1)

where m is a diffraction order, λ is a wavelength, α is the incident angle, β is the diffraction angle, and a is a groove pitch.

An irradiation width W irradiated with the pulsed laser light beam 30 in the first grating 41 may be substantially equal to a length of the first grating 41, and may be determined by the following expression.

W=D1/cos α (2)

where D1 is a beam diameter of the pulsed laser light beam 30.

The groove number N irradiated with the pulsed laser light beam 30 may be determined by the following expression.

N=W/a (3)

An optical path difference ΔL between both ends of the pulsed laser light beam 30 may be determined by the following expression.

ΔL=mλ·N (4)

The delay time ΔT of the pulsed laser light beam 30 may be determined by the following expression.

ΔT=ΔL/c (5)

where c is light velocity.

A blaze angle φ of the first grating 41 may be determined by the following expression.

φ=α−(α+β)/2 (6)

### (Specifications of Grating)

Table 1 illustrates specifications of the first grating 41 that achieves the delay time ΔT in a range from about 0.51 ns to about 1 ns when the beam diameter D1 of the pulsed laser light beam 30 outputted from the free electron laser apparatus 3 is, for example, about 10 mm. A wavelength of the pulsed laser light beam 30 is 13.5 nm or 6.7 nm.

As can be seen from Table 1, a length in a dispersion direction of the first grating 41 corresponding to the irradiation width W may fall within a range from about 280 mm to about 1145 mm, the groove pitch a may fall within a range from about 2.5 μm to about 5 μm, and the blaze angle φ may fall within a range from about 58° to about 68°. The incident angle α may fall within a range from about 88° to about 89.5°, and the diffraction angle β may fall within a range from about 28° to about 47°.

In terms of tolerance of the first grating 41, the incident angle α (where α<90° may be preferably as close to 90° as possible, and the first grating 41 may be preferably long. Increasing the irradiation width W irradiated with the pulsed laser light beam 30 in the first grating 41 may make it possible to reduce energy density of the pulsed laser light beam 30 and suppress laser ablation on the surface of the first grating 41.

TABLE 1

| | Beam Diameter | Wavelength | Incident Angle | Irradiation Width | | Diffraction Angle |
|---|---|---|---|---|---|---|
| No. | D1 (mm) | λ (nm) | α (degree) | W (mm) | Order m | β (degree) |
| 1 | 10 | 13.5 | 88 | 286.54 | 100 | 28 |
| 2 | 10 | 13.5 | 88.5 | 382.02 | 100 | 28 |
| 3 | 10 | 13.5 | 89 | 572.99 | 100 | 28 |
| 4 | 10 | 13.5 | 89.5 | 1145.93 | 100 | 47 |
| 5 | 10 | 6.7 | 88 | 286.54 | 200 | 28 |
| 6 | 10 | 6.7 | 88.5 | 382.02 | 200 | 28 |
| 7 | 10 | 6.7 | 89 | 572.99 | 200 | 28 |
| 8 | 10 | 6.7 | 89.5 | 1145.93 | 200 | 47 |

| | Groove Pitch | Groove Number | Optical Path Difference | Delay Time | Blaze Angle |
|---|---|---|---|---|---|
| No. | a (m) | N = W/d | ΔL (m) | ΔT (ns) | φ (degree) |
| 1 | 2.55E−06 | 112475 | 0.15 | 0.51 | 58 |
| 2 | 2.55E−06 | 150029 | 0.20 | 0.68 | 58.25 |
| 3 | 2.55E−06 | 225110 | 0.30 | 1.01 | 58.5 |
| 4 | 5.03E−06 | 228005 | 0.31 | 1.03 | 68.25 |
| 5 | 2.53E−06 | 113315 | 0.15 | 0.51 | 58 |
| 6 | 2.53E−06 | 151149 | 0.20 | 0.68 | 58.25 |
| 7 | 2.53E−06 | 226790 | 0.30 | 1.01 | 58.5 |
| 8 | 4.99E−06 | 229706 | 0.31 | 1.03 | 68.25 |

Moreover, Table 2 and Table 3 illustrate a relationship of the delay time ΔT with respect to the incident angle α to the first grating 41.

As can be seen from Table 2 and Table 3, the incident angle α in a case in which the delay time ΔT is 0.1 ns or more may fall within the following range.

72°≦α<90°

Moreover, the incident angle α in a case in which the delay time ΔT is 0.2 ns or more may fall within the following range.

80.5°≦α<90°

Further, the incident angle α in a case in which the delay time ΔT is 1 ns or more may fall within the following range.

88.1°≦α<90°

The optical path difference ΔL=mλN in the case in which the delay time ΔT is 0.1 ns or more may fall within the following range.

0.031(m)≦mλN<1.146(m)

Moreover, the optical path difference ΔL=mλN in the case in which the delay time ΔT is 0.2 ns or more may fall within the following range.

0.060(m)≦mλN<1.146(m)

Further, the optical path difference ΔL=mλN in the case in which the delay time ΔT is 1 ns or more may fall within the following range.

0.301(m)≦mλN<1.146(m)

TABLE 2

| | Beam Diameter | Wavelength | Incident Angle | Irradiation Width | | Diffraction Angle |
|---|---|---|---|---|---|---|
| No. | D1 (mm) | λ (nm) | α (degree) | W (mm) | Order m | β (degree) |
| 1 | 10 | 13.5 | 70 | 29.24 | 100 | 0 |
| 2 | 10 | 13.5 | 71 | 30.72 | 100 | 0 |
| 3 | 10 | 13.5 | 72 | 32.36 | 100 | 0 |
| 4 | 10 | 13.5 | 73 | 34.20 | 100 | 0 |
| 5 | 10 | 13.5 | 74 | 36.28 | 100 | 0 |
| 6 | 10 | 13.5 | 75 | 38.64 | 100 | 0 |
| 7 | 10 | 13.5 | 77 | 44.45 | 100 | 0 |
| 8 | 10 | 13.5 | 78 | 48.10 | 100 | 0 |
| 9 | 10 | 13.5 | 79 | 52.41 | 100 | 0 |
| 10 | 10 | 13.5 | 80 | 57.59 | 100 | 0 |

| | Groove Pitch | Groove Number | Optical Path Difference | Delay Time | Blaze Angle |
|---|---|---|---|---|---|
| No. | a (m) | N = W/d | ΔL (m) | ΔT (ns) | φ (degree) |
| 1 | 1.44E−06 | 20351.68 | 0.027 | 0.092 | 35 |
| 2 | 1.43E−06 | 21512.67 | 0.029 | 0.097 | 35.5 |
| 3 | 1.42E−06 | 22797.66 | 0.031 | 0.103 | 36 |
| 4 | 1.41E−06 | 24228.54 | 0.033 | 0.109 | 36.5 |
| 5 | 1.40E−06 | 25832.7 | 0.035 | 0.116 | 37 |
| 6 | 1.40E−06 | 27644.82 | 0.037 | 0.124 | 37.5 |
| 7 | 1.39E−06 | 32085.01 | 0.043 | 0.144 | 38.5 |
| 8 | 1.38E−06 | 34849.11 | 0.047 | 0.157 | 39 |
| 9 | 1.38E−06 | 38107.81 | 0.051 | 0.171 | 39.5 |
| 10 | 1.37E−06 | 42009.49 | 0.057 | 0.189 | 40 |

TABLE 3

| | Beam Diameter | Wavelength | Incident Angle | Irradiation Width | | Diffraction Angle |
|---|---|---|---|---|---|---|
| No. | D1 (mm) | λ (nm) | α (degree) | W (mm) | Order m | β (degree) |
| 11 | 10 | 13.5 | 80.5 | 60.59 | 100 | 0 |
| 12 | 10 | 13.5 | 82 | 71.85 | 100 | 0 |
| 13 | 10 | 13.5 | 83 | 82.06 | 100 | 0 |
| 14 | 10 | 13.5 | 84 | 95.67 | 100 | 0 |
| 15 | 10 | 13.5 | 85 | 114.74 | 100 | 0 |
| 16 | 10 | 13.5 | 86.2 | 150.89 | 100 | 0 |
| 17 | 10 | 13.5 | 87 | 191.07 | 100 | 0 |
| 18 | 10 | 13.5 | 88.1 | 301.61 | 100 | 0 |
| 19 | 10 | 13.5 | 89 | 572.99 | 100 | 0 |
| 20 | 10 | 13.5 | 89.5 | 1145.93 | 100 | 0 |

| | Groove Pitch | Groove Number | Optical Path Difference | Delay Time | Blaze Angle |
|---|---|---|---|---|---|
| No. | a (m) | N = W/d | ΔL (m) | ΔT (ns) | φ (degree) |
| 11 | 1.37E−06 | 44264.92 | 0.060 | 0.199 | 40.25 |
| 12 | 1.36E−06 | 52706.44 | 0.071 | 0.237 | 41 |
| 13 | 1.36E−06 | 60328.49 | 0.081 | 0.271 | 41.5 |
| 14 | 1.36E−06 | 70476.77 | 0.095 | 0.317 | 42 |
| 15 | 1.36E−06 | 84667.05 | 0.114 | 0.381 | 42.5 |
| 16 | 1.35E−06 | 111523.9 | 0.151 | 0.502 | 43.1 |
| 17 | 1.35E−06 | 141341.8 | 0.191 | 0.636 | 43.5 |
| 18 | 1.35E−06 | 223293.5 | 0.301 | 1.005 | 44.05 |
| 19 | 1.35E−06 | 424370.1 | 0.573 | 1.910 | 44.5 |
| 20 | 1.35E−06 | 848804.8 | 1.146 | 3.820 | 44.75 |

(3.3 Effect)

According to the first embodiment, the pulsed laser light beam 30 outputted from the free electron laser apparatus 3 obliquely enters the first grating 41 serving as the delaying optical system 40, which makes it possible to spatially delay the pulsed laser light beam 30 depending on a diffraction position of the pulsed laser light beam 30. Thereafter, the pulsed laser light beam 30 converted into the diffracted light beam 30g by the first grating 41 may be concentrated near the predetermined focus point P1 by the off-parabolic mirror 13. This makes it possible to increase the pulse width of the pulsed laser light beam 30 near the predetermined focus point P1. Moreover, the pulsed laser light beam 30 converted into the diffracted light beam 30g may be expanded in a grating dispersion direction, as compared with the pulsed laser light beam 30 having entered the first grating 41.

The pulsed laser light beam 30 converted into the diffracted light beam 30g is transmitted to the exposure apparatus 2 to generate illumination light spatially uniformized by the illumination optical system 21, which makes it possible to increase the pulse width of a beam to be applied onto the mask 22 or the wafer 24. This makes it possible to suppress ablation in a resist on any of various kinds of optical elements and the wafer 24 in the exposure apparatus 2.

Moreover, in the pulsed laser light beam 30 converted into the diffracted light beam 30g, spatial coherence in an YZ plane direction that is a light dispersion direction by the first grating 41 may be reduced. This makes it possible to suppress generation of a speckle in the exposure apparatus 2.

### 3.4 Modification Examples

In the foregoing embodiment in FIG. 2 and FIG. 3, the diffracted light beam 30g is concentrated by the off-parabolic mirror 13, and enters the exposure apparatus 2. However, the present embodiment is not limited thereto. The diffracted light beam 30g may directly enter the illumination optical system 21 of the exposure apparatus 2 without using the off-parabolic mirror 13.

In addition, the following modification examples of the foregoing embodiment in FIG. 2 and FIG. 3 may be adopted.

### 3.4.1 First Modification Example (Modification Example of Shape of Groove of Grating)

In the foregoing embodiment in FIG. 3, the blazed grating is described as an example of the first grating 41; however, the first grating 41 is not limited thereto. For example, the first grating 41 may be a holographic grating that is provided with grooves having a sinusoidal wave shape on a surface thereof. Moreover, the surface shape of the first grating 41 may be a rectangular wave shape or any shape other than the sinusoidal wave shape and the triangular wave shape.

In processing of the first grating 41, groove processing by a diamond tool of a ruling engine or groove processing by an ion beam sputtering method or a semiconductor process may be performed on a substrate, and thereafter the substrate may be coated with a high reflection film such as a single-layer film of Ru or a multilayer film of Mo and Si, for example. In a case in which it is difficult to process the substrate, for example, the substrate may be coated with a smoothing layer such as Ni—P, and groove processing may be performed on the smoothing layer. In a case in which the groove pitch a is small, for example, 1 μm or less, the substrate may be coated with the high reflection film, and thereafter etching may be performed on the substrate by an ion beam sputtering method or a semiconductor process. Moreover, examples of a high reflection film for EUV light of a wavelength of 6.7 nm may include a single-layer film of Ru and a multilayer film of CaB₆ and BaB₆.

FIG. 5 schematically illustrates a first modification example of the shape of each of the grooves of the first grating 41.

Grooves 51 may be formed as follows. A substrate 50 may be coated with a multilayer film 52 such as a multilayer film of Mo/Si, and thereafter the multilayer film 52 may be etched to a predetermined depth by a semiconductor process, an ion beam sputtering method, or any other method to allow the predetermined diffracted light beam 30g to be strongly diffracted, as illustrated in FIG. 5.

FIG. 6 schematically illustrates a second modification example of the shape of each of the grooves of the first grating 41.

The grooves 51 may be formed as follows. The substrate 50 may be etched to a predetermined depth by a semiconductor process, an ion beam sputtering method, or any other method to allow the predetermined diffracted light beam 30g to be strongly diffracted. After the grooves 51 are formed, surfaces of the grooves 51 may be coated with a single-layer film of Ru.

As can be seen from Table 4, using the semiconductor process makes it possible to reduce the groove pitch a and the diffraction order m and increase diffraction efficiency.

TABLE 4

| Beam Diameter | Wavelength | Incident Angle | Irradiation Width | Order | Diffraction Angle |
|---|---|---|---|---|---|
| D1 (mm) | λ (nm) | α (degree) | W (mm) | m | β (degree) |
| 10 | 13.5 | 88 | 286.54 | 10 | 0 |
| Groove Pitch | Groove Number | Optical Path Difference | Delay Time | Groove Shape | |
| a (m) | N = W/d | ΔL (m) | ΔT (ns) | | |
| 1.35E−07 | 2121204 | 0.29 | 0.95 | Rectangular | |

FIG. 7 schematically illustrates a third modification example of the shape of each of the grooves of the first grating 41.

As examples of the shape of each of the grooves, FIG. 3 illustrates a triangular wave shape, and FIG. 5 and FIG. 6 illustrate a rectangular wave shape; however, the shape of each of the groove may be a sinusoidal wave shape as illustrated in FIG. 7.

### 3.4.2 Second Modification Example (Connection of a Plurality of Gratings)

FIG. 8 schematically illustrates a configuration example in which a plurality of gratings are connected together.

In a case in which the pulsed laser light beam 30 obliquely enters the first grating 41, for example, the length of the first grating 41 may be extremely long as with configuration examples in Nos. 3, 4, 7, and 8 of above Table 1, and the first grating 41 may not be fabricated as a single body. For example, in a case in which the first grating 41 has a length of 500 mm or more, it may be extremely difficult to fabricate the first grating 41 as a single body. Therefore, FIG. 8 illustrates an embodiment of a grating system that is configured of a connection of a plurality of gratings and includes a mechanism of adjusting a wavefront of the diffracted light beam 30g by the gratings.

The grating system may include a first grating 41-1, a second grading 41-2, and a third grating 41-3 that are connected together to configure one first grating 41. The grating system may further include a holder 61 and a controller 60.

The holder 61 may include a first plate 63, first to sixth actuators 62-1 to 62-6, and a second plate 64. The first grating 41-1, the second grading 41-2, and the third grating 41-3 may be disposed on the first plate 63. A back surface of the first plate 63 may be fixed to the second plate 64 with the first to sixth actuators 62-1 to 62-6 in between.

The first to sixth actuators 62-1 to 62-6 may be controlled to expand and contract in response to output of a control signal from the controller 60. The wavefront of the diffracted light beam 30g by the first to third gratings 41-1 to 41-3 may be adjusted through the first plate 63 by expansion and contraction of the first to sixth actuators 62-1 to 62-6.

The controller 60 may control the first to sixth actuators 62-1 to 62-6 to suppress distortion of the wavefront of the diffracted light beam 30g by the first to third gratings 41-1 to 41-3.

According to the grating system, a plurality of gratings are provided side by side, and distortion of the wavefront of the diffracted light beam 30g is suppressed. This makes it possible for the connection of the gratings to function as one long grating.

It is to be noted that an unillustrated wavefront sensor may be added to the configuration illustrated in FIG. 8. The wavefront sensor may detect the wavefront of the diffracted light beam 30g. The controller 60 may control each of the first to sixth actuators 62-1 to 62-6 on the basis of a thus-obtained detection result. The wavefront sensor may be a Shack-Hartmann interferometer for EUV light. Alternatively, unillustrated visible guide light may enter the grating, and the wavefront sensor may measure a wavefront of a diffracted light beam of the visible guide light.

Moreover, the system illustrated in FIG. 8 may be applied to a multiple mirror system 70 described in the following embodiment, or any other system. In this case, the multiple mirror system 70 or any other system may be provided in place of the grating, and a plurality of actuators corresponding to the number of mirrors and the positions of the mirrors may be provided. The controller 60 may control the actuators to suppress distortion of a wavefront of reflected light by the multiple mirror system 70 or any other system.

### 3.4.3 Third Modification Example (Modification Example in which Position of Grating is Changed)

In the foregoing embodiment in FIG. 2 and FIG. 3, in the beam transmission system 4, the first grating 41 serving as the delaying optical system 40 is disposed following the undulator 31 of the free electron laser apparatus 3. Alternatively, the delaying optical system 40 may be disposed at a position different from the above-described position.

### (Configuration)

FIG. 9 illustrates a configuration example in which the position of the first grating 41 is changed as a modification example of the beam transmission system 4.

A beam transmission system 4A illustrated in FIG. 9 may include, in place of the off-parabolic mirror 13, a beam expander 5 including a first off-parabolic mirror 15 and a second off-parabolic mirror 16. The beam expander 5 may be provided in an optical path between the undulator 31 and the first grating 41. The first off-parabolic mirror 15 and the second off-parabolic mirror 16 may be disposed to allow focus points P2 of the first off-parabolic mirror 15 and the second parabolic mirror 16 to be substantially coincident with each other.

The incident angle of the pulsed laser light beam 30 with respect to each of the first off-parabolic mirror 15 and the second off-parabolic mirror 16 may be less than 90° and preferably large. The diffracted light beam 30g by the first grating 41 may directly enter the illumination optical system 21 of the exposure apparatus 2 without providing the off-parabolic mirror 13 such as the configuration example in FIG. 3 on downstream side of the first grating 41.

### (Operation)

In the beam transmission system 4A, the pulsed laser light beam 30 outputted from the undulator 31 may be expanded by the beam expander 5. Pulse timing of the expanded pulsed laser light beam 30 may be delayed depending on a position where the pulsed laser light beam 30 is diffracted by the first grating 41.

### (Effect)

According to the beam transmission system 4A, the pulsed laser light beam 30 is expanded before entering the first grating 41, which makes it possible to increase lifetime of the first grating 41. In a case in which the beam diameter D1 of the pulsed laser light beam 30 outputted from the undulator 31 is small, for example, about several millimeters, the expanded pulsed laser light beam 30 may preferably enter the first grating 41 in some cases.

### 4. Second Embodiment (Embodiment of Beam Transmission System Including Two Gratings)

Next, description is given of a second embodiment of the present disclosure with reference to FIG. 10. Note that substantially same components as the components of the EUV light source system 1, the exposure apparatus 2, and other systems and apparatuses according to the foregoing first embodiment are denoted by same reference numerals, and redundant description thereof is omitted.

### 4.1 Configuration

Description of the foregoing embodiment in FIG. 3 involves a configuration example in which one first grating 41 is provided as the delaying optical system 40 in the beam transmission system 4. However, two or more gratings may be provided as the delaying optical system 40.

FIG. 10 illustrates an embodiment including two gratings as another embodiment of the beam transmission system 4 in FIG. 3. A beam transmission system 4B illustrated in FIG. 10 may include, as the delaying optical system 40, a second grating 42 in addition to the first grating 41.

The first grating 41 may generate a first diffracted light beam as the diffracted light beam 30g of the pulsed laser light beam 30. The second grating 42 may diffract the first diffracted light beam by the first grating 41 to generate a second diffracted light beam. The first grating 41 may include a first dispersion surface where the pulsed laser light beam 30 enters, and the second grating 42 may include a second dispersion surface where the first diffracted light beam enters. The first grating 41 and the second grating 42 may be disposed substantially orthogonal to each other to allow the first dispersion surface and the second dispersion surface to be substantially orthogonal to each other. The pulsed laser light beam 30 converted into the second diffracted light beam by the second grating 42 may enter the exposure apparatus 2 via the off-parabolic mirror 13.

The groove pitch a, the incident angle α and the diffraction angle β of the pulsed laser light beam 30 in the second grating 42 may be substantially the same as those in the first grating 41. A width of the second grating 42 in a direction perpendicular to a dispersion direction may be equal to or larger than the beam width D2 of the first diffracted light beam by the first grating 41.

### 4.2 Operation

In the beam transmission system 4B illustrated in FIG. 10, the pulsed laser light beam 30 outputted from the free electron laser apparatus 3 may be diffracted by the first grating 41 and the second grating 42. The pulsed laser light beam 30 diffracted by each of the first grating 41 and the second grating 42 may have an optical path difference depending on a position where the pulsed laser light beam 30 is diffracted. As a result, pulse timing of the pulsed laser light beam 30 diffracted by the first grating 41 may be delayed depending on the position where the pulsed laser light beam 30 is diffracted by the first grating 41. The pulse timing of the pulsed laser light beam 30 may be further delayed depending on the position where the pulsed laser light beam 30 is diffracted by the second grating 42. In other words, the pulse timing may be additionally delayed depending on the position where the pulsed laser light beam 30 is diffracted by the second grating 42. The pulsed laser light beam 30 diffracted by the second grating 42 may be concentrated near the predetermined focus point P1 by the off-parabolic mirror 13. The pulse width of the pulsed laser light beam 30 near the predetermined focus point P1 may increase.

### 4.3 Effect

According to the second embodiment, the pulsed laser light beam 30 is diffracted twice by the first grating 41 and the second grating 42, which makes it possible to increase the delay time ΔT to about twice the delay time ΔT in the case in which only one grating is provided. Moreover, the first grating 41 and the second grating 42 are disposed to allow the dispersion surfaces of the first grating 41 and the second grating 42 to be substantially orthogonal to each other, thereby diffracting the pulsed laser light beam 30 twice. This makes it possible to expand the pulsed laser light beam 30 in both the YZ plane direction and an XZ plane direction. The pulsed laser light beam 30 diffracted twice may be concentrated near the predetermined focus point P1 by the off-parabolic mirror 13. This makes it possible to expand the pulse width of the pulsed laser light beam 30 to about twice the pulse width in the case in which only one grating is provided.

Further, in the pulsed laser light beam 30 diffracted twice, spatial coherence in the YZ plane direction and the XZ plane direction may be reduced. This makes it possible to further suppress generation of a speckle in the exposure apparatus 2, as compared with the embodiment in FIG. 3.

### 4.4 Modification Example

In the foregoing embodiment in FIG. 10, the second diffracted light beam by the second grading 42 is concentrated by the off-parabolic mirror 13 to enter the exposure apparatus 2. However, the embodiment is not limited thereto. The off-parabolic mirror 13 may be omitted from the configuration. Further, the second diffracted light beam by the second grating 42 may directly enter the illumination optical system 21 of the exposure apparatus 2 without using the off-parabolic mirror 13.

### 5. Third Embodiment (Embodiment of Beam Transmission System Including Multiple Mirror System)

Next, description is given of a third embodiment of the present disclosure with reference to FIG. 11 and other drawings. Note that substantially same components as the components of the EUV light source system, the exposure apparatus, and other systems and apparatuses according to the foregoing first embodiment or the foregoing second embodiment are denoted by same reference numerals, and redundant description thereof is omitted.

### 5.1 Configuration

FIG. 11 schematically illustrates a configuration example of a beam transmission system 4C according to the present embodiment. Description of the foregoing first and second embodiments involves a configuration example using the grating as the delaying optical system 40. However, in place of the grating, the multiple mirror system 70 may be provided as the delaying optical system 40, as illustrated in FIG. 11. The multiple mirror system 70 may be provided in an optical path between the free electron laser apparatus 3 and the off-parabolic mirror 13 in the chamber 10.

FIG. 12 schematically illustrates a specific configuration example of the multiple mirror system 70.

The multiple mirror system 70 may include a plurality of mirrors. The multiple mirror system 70 may include a plurality of reflection surfaces 71 and a step surface 72. Each of the reflection surfaces 71 may configure one of the mirrors. The multiple mirror system 70 may reflect the pulsed laser light beam 30 by the plurality of reflection surfaces 71 to generate a plurality of reflected light beams 30r having an optical path difference with respect to one another.

The multiple mirror system 70 may be configured to allow an optical path difference δL of the plurality of reflected light beams 30r and a pulse width ΔD of the pulsed laser light beam 30 outputted from the free electron laser apparatus 3 to satisfy the following relationship.

δL≧c·ΔD (7)

where c is light velocity.

For example, the pulse width ΔD may be a full width at half maximum of peak intensity of a time waveform of the pulsed laser light beam 30 outputted from the free electron laser apparatus 3.

A difference d between the reflection surfaces 71 illustrated in FIG. 12 may satisfy the following relationship in a case in which the pulsed laser light beam 30 enters the reflection surfaces 71 at an incident angle γ, as illustrated in FIG. 11. In this case, for example, the difference d may be equal to or larger than 31 μm in a case in which the pulse width of the pulsed laser light beam 30 is 0.2 ps, and the incident angle γ is 15°.

d≧δL/(2 cos γ) (8)

A shape of one of the mirrors of the multiple mirror system 70 may be a quadrangular prism shape. The reflection surface 71 of each of the mirrors may be coated with a reflection film. The reflection film may be a single-layer film of Ru or a multilayer film of Mo and Si. The mirrors may be 5 by 5=25 mirrors that are tied in a bundle. The mirrors may be bonded or welded together to allow the reflected light beams 30r by the reflection surfaces 71 to have the optical path difference δL with respect to one another.

### 5.2 Operation

In the beam transmission system 4C illustrated in FIG. 11, the pulsed laser light beam 30 with the beam diameter D1 outputted from the free electron laser apparatus 3 may enter the multiple mirror system 70 at the incident angle γ to be reflected by the plurality of reflection surfaces 71. Thus, the plurality of reflected light beams 30r may be generated. At this occasion, the pulsed laser light beam 30 reflected by the multiple mirror system 70 may have an optical path difference depending on a position where the pulsed laser light beam 30 is reflected by the multiple mirror system 70. As a result, the pulse timing of the pulsed laser light beam 30 converted into the plurality of reflected light beams 30r may be delayed depending on the position where the pulsed laser light beam 30 is reflected. In other words, the pulsed laser light beam 30 with the beam diameter D1 outputted from the free electron laser apparatus 3 may be delayed by the multiple mirror system 70 to allow the amount of delay of the pulsed laser light beam 30 to be varied depending on the position in the beam cross-section in the direction not parallel to the optical path, for example, the oblique direction of the pulsed laser light beam 30. At this occasion, the pulsed laser light beam 30 may be spatially divided into a plurality of segments in the beam cross-section in accordance with the shape of each of the mirrors of the multiple mirror system 70 to vary the amount of delay for each of the segments.

The pulsed laser light beam 30 converted into the plurality of reflected light beams 30r may be concentrated near the predetermined focus point P1 by the off-parabolic mirror 13. The reflected light beams 30r by the multiple mirror system 70 are concentrated near the predetermined focus point P1 in the right bottom section of FIG. 11, which may cause the pulse width of the reflected light beam 30r near the predetermined focus point P1 to increase.

The optical path difference ΔL of the entirety of the multiple mirror system 70 may be determined as follows, where the number of mirrors is J.

ΔL=J·δL (9)

For example, in a case in which the number J of mirrors is 25 and the optical path difference δL is 60 μm, the pulse width may increase from 0.2 ps to 5 ps (equal to 25 multiplied by 0.2).

### 5.3 Effect

According to the third embodiment, the pulsed laser light beam 30 outputted from the free electron laser apparatus 3 may be reflected by the multiple mirror system 70 serving as the delaying optical system 40 to spatially delay the pulsed laser light beam 30 depending on a reflection position of the pulsed laser light beam 30. Thereafter, the pulsed laser light beam 30 converted into the plurality of reflected light beams 30r by the multiple mirror system 70 may be concentrated near the predetermined focus point P1 by the off-parabolic mirror 13. This makes it possible to increase the pulse width of the pulsed laser light beam 30 near the predetermined focus point P1.

The concentrated pulsed laser light beam 30 is transmitted to the exposure apparatus 2 to generate illumination light spatially uniformized by the illumination optical system 21, which makes it possible to increase the pulse width of a beam to be applied onto the mask 22 or the wafer 24. This make it possible to suppress ablation in a resist on any of various kinds of optical elements and the wafer 24 in the exposure apparatus 2 illustrated in FIG. 1.

Each of the pulsed laser light beams 30 reflected by the multiple mirror system 70 may have an optical path difference equal to or longer than the pulse width of the pulsed laser light beam 30 outputted from the free electron laser apparatus 3, which makes it possible to suppress interference of the pulsed laser light beams 30. This makes it possible to suppress generation of a speckle in the exposure apparatus 2.

### 5.4 Modification Examples

In the foregoing embodiment in FIG. 11, the plurality of reflected light beams 30r may be concentrated by the off-parabolic mirror 13 to enter the exposure apparatus 2. However, the embodiment is not limited thereto. The plurality of reflected light beams 30r may directly enter the illumination optical system 21 of the exposure apparatus 2 without using the off-parabolic mirror 13. For example, the pulsed laser light beam 30 reflected by each of the mirrors of the multiple mirror system 70 may enter the secondary light source formation-use multiple concave mirror 26 illustrated in FIG. 1. This makes it possible to further suppress generation of a speckle on the mask 22.

Moreover, description of the foregoing embodiment in FIG. 12 involves an example in the case in which the multiple mirror system 70 includes 25 mirrors. The multiple mirror system 70 is not limited thereto. The multiple mirror system 70 may include more mirrors, for example, 1000 or 10000 mirrors. In a case in which the multiple mirror system 70 includes 10000 mirrors, the pulse width may be increased to 2 ns.

Further, description of the foregoing embodiment in FIG. 12 involves an example in which the shape of each of the mirrors is a quadrangular prism shape; however, the shape of each of the mirrors is not limited thereto. A single substrate may be processed to form a plurality of mirrors in the single substrate, and the reflection surfaces 71 may be coated with a high reflection film.

FIG. 13 schematically illustrates a first modification example of the shape of each of the reflection surfaces 71 of the multiple mirror system 70. FIG. 14 schematically illustrates a second modification example of the shape of each of the reflection surfaces 71 of the multiple mirror system 70. Description of the foregoing embodiment in FIG. 12 involves an example in which the shape of each of the reflection surfaces 71 is a flat shape. However, the embodiment is not limited thereto. The flat reflection surface 71 may be replaced by a concave reflection surface 73, as illustrated in a bottom section of FIG. 13. Alternatively, the flat reflection surface 71 may be replaced by a convex reflection surface 74, as illustrated in a bottom section of FIG. 14.

### 6. Fourth Embodiment (Embodiment of Beam Transmission System Including Two Multiple Mirror Systems)

Next, description is given of a fourth embodiment of the present disclosure with reference to FIG. 15 and other drawings. Note that substantially same components as the components of the EUV light source system, the exposure apparatus, and other systems and apparatuses according to the foregoing first to third embodiments are denoted by same reference numerals, and redundant description thereof is omitted.

### 6.1 Configuration

Description of the foregoing embodiment in FIG. 11 involves a configuration example in which one multiple mirror system 70 is provided as the delaying optical system 40 in the beam transmission system 4C. However, two or more multiple mirror systems may be provided as the delaying optical system 40.

As with the beam transmission system 4D illustrated in FIG. 15, for example, in place of one multiple mirror system 70, a first multiple mirror system 80A and a second multiple mirror system 80B may be included as the delaying optical system 40. The first and second multiple mirror systems 80A and 80B may be provided in an optical path between the free electron laser apparatus 3 and the off-parabolic mirror 13 in the chamber 10.

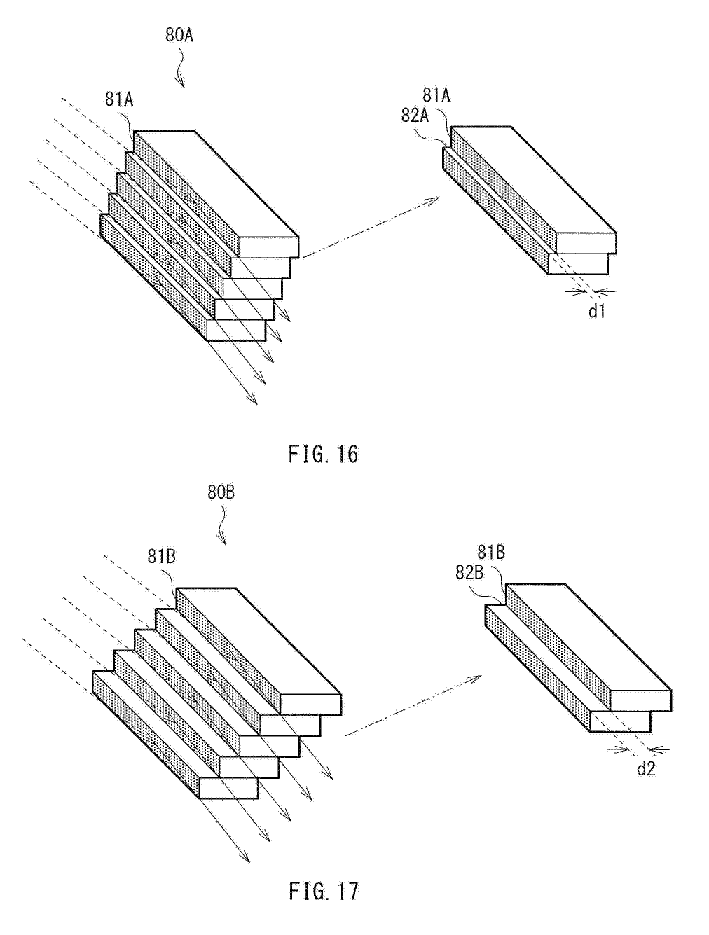

FIG. 16 schematically illustrates a specific configuration example of the first multiple mirror system 80A. FIG. 17 schematically illustrates a specific configuration example of the second multiple mirror system 80B. The first and second multiple mirror systems 80A and 80B may each include a plurality of mirrors.

The first multiple mirror system 80A may include a plurality of reflection surfaces 81A and step surfaces 82A, as illustrated in FIG. 16. Each of the reflection surfaces 81A may configure one of the mirrors. The first multiple mirror system 80A may reflect the pulsed laser light beam 30 by the plurality of reflection surfaces 81A to generate a plurality of first reflected light beams as the plurality of reflected light beams 30r having an optical path difference with respect to one another.

The second multiple mirror system 80B may include a plurality of reflection surfaces 81B and step surfaces 82B, as illustrated in FIG. 17. Each of the reflection surfaces 81B may configure one of the mirrors. The second multiple mirror system 80B may further reflect the plurality of first reflected light beams from the first multiple mirror system 80A to generate a plurality of second reflected light beams having an optical path difference with respect to one another. The pulsed laser light beam 30 converted into the second reflected light beams by the second multiple mirror system 80B may enter the exposure apparatus 2 through the off-parabolic mirror 13.

The first multiple mirror system 80A may have a first incident surface where the pulsed laser light beam 30 enters, and the second multiple mirror system 80B may have a second incident surface where the first reflected light beam enters. The first multiple mirror system 80A and the second multiple mirror system 80B may be disposed substantially orthogonal to each other to allow the first incident surface and the second incident surface to be substantially orthogonal to each other.

The reflection surfaces 81A and 81B of the first and second multiple mirror systems 80A and 80B may each have a rectangular shape.

As a specific example, the first and second multiple mirror systems 80A and 80B may be configured as follows, for example.

For example, it is assumed that the pulse width ΔD of the pulsed laser light beam 30 outputted from the free electron laser apparatus 3 is 0.2 ps. A difference d1 between adjacent two of the reflection surfaces 81A in the first multiple mirror system 80A illustrated in FIG. 16 may satisfy the following condition in a case in which the incident angle γ of a light beam to each of the reflection surfaces 81A of the first multiple mirror system 80A is 80°.

d1≧173 μm

A difference d2 between adjacent two of the plurality of reflection surfaces 81B in the second multiple mirror system 80B illustrated in FIG. 17 may satisfy the following conditions, where the number of mirrors of the first multiple mirror system 80A is J.

d2≧J·d1 (10)

From the expression (10), the difference d2 between adjacent two of the reflection surfaces 81B illustrated in FIG. 17 may satisfy the following condition in a case in which the incident angle γ of the light beam to each of the reflection surfaces 81B in the second multiple mirror system 80B is 80°.

d2≧865 μm

Moreover, the first and second multiple mirror systems 80A and 80B may each include five mirrors, as illustrated in FIG. 16 and FIG. 17. In this case, widths of the reflection surfaces 81A and 81B of the mirrors may be 1000 μm, for example. Each of the reflection surfaces 81A and 81B may be coated with a reflection film. The reflection film may be a single-layer film of Ru or a multilayer film of Mo and Si. Alternatively, the reflection film may be a multilayer film such as a multilayer film of CaB₆ and BaB₆.

### 6.2 Operation

In the beam transmission system 4D illustrated in FIG. 15, the pulsed laser light beam 30 outputted from the free electron laser apparatus 3 may be reflected by the first and second multiple mirror systems 80A and 80B. The pulsed laser light beam 30 reflected by the reflection surfaces 81A and 81B of the first and second multiple mirror systems 80A and 80B may have an optical path difference depending on the position where the pulsed laser light beam 30 is reflected. As a result, pulse timing of the pulsed laser light beam 30 reflected by the first multiple mirror system 80A may be delayed depending on the position where the pulsed laser light beam 30 is reflected by the first multiple mirror system 80A. The pulse timing of the pulsed laser light beam 30 may be further delayed depending on the position where the pulsed laser light beam 30 is reflected by the second multiple mirror system 80B. In other words, the pulse timing may be additionally delayed depending on the position where the pulsed laser light beam 30 is reflected by the second multiple mirror system 80B. The pulsed laser light beam 30 reflected by the second multiple mirror system 80B may be concentrated near the predetermined focus point P1 by the off-parabolic mirror 13. The pulse width of the pulsed laser light beam 30 near the predetermined focus point P1 may increase.

Each of the first and second multiple mirror systems 80A and 80B may generate a plurality of reflected light beams having the optical path difference δL. The optical path difference ΔL of the entirety of the first and second multiple mirror systems 80A and 80B may be determined as follows, where the number of mirrors in each of the first and second multiple mirror systems 80A and 80B is J.

ΔL=J²·δL (11)

In each of the first and second multiple mirror systems 80A and 80B, in a case in which the number J of mirrors is 5 and the optical path difference δL is 60 μm, the pulse width may increase from 0.2 ps to 5 ps (equal to 25 multiplied by 0.2).

### 6.3 Effect

According to the fourth embodiment, the pulsed laser light beam 30 is reflected twice by the first and second multiple mirror systems 80A and 80B, which makes it possible to increase the delay time ΔT to about the square of the delay time ΔT in a case in which only one multiple mirror system is provided. The pulsed laser light beam 30 reflected twice may be concentrated near the predetermined focus point P1 by the off-parabolic mirror 13. This makes it possible to increase the pulse width of the pulsed laser light beam 30 to about the square of the pulse width of the pulsed laser light beam 30 in the case in which only one multiple mirror system is provided.

Further, in the pulsed laser light beam 30 reflected twice, spatial coherence in the YZ plane direction and the XZ plane direction may be reduced. This makes it possible to further suppress generation of a speckle in the exposure apparatus 2, as compared with the case in which only one multiple mirror system is provided.

Furthermore, in each of the first and second multiple mirror systems 80A and 80B, the pulsed laser light beam 30 obliquely enters each of the reflection surfaces 81A and 81B, for example, at the incident angle γ of 80°. This makes it possible to increase reflectivity. In addition, this makes it possible to reduce energy density of the pulsed laser light beam 30 that enters each of the reflection surfaces 81A and 81B.

### 6.4 Modification Examples

In the foregoing embodiment in FIG. 15, the second reflected light beam by the second multiple mirror system 80B is concentrated by the off-parabolic mirror 13 to enter the exposure apparatus 2. However, the embodiment is not limited thereto. The off-parabolic mirror 13 may be omitted from the configuration. Further, the second reflected light beam by the second multiple mirror system 80B may directly enter the illumination optical system 21 of the exposure apparatus 2 without using the off-parabolic mirror 13. For example, the pulsed laser light beam 30 reflected by each of the mirrors of the second multiple mirror system 80B may enter the secondary light source formation-use multiple concave mirror 26 illustrated in FIG. 1. This makes it possible to further suppress generation of a speckle on the mask 22.

Moreover, description of the foregoing embodiment in FIGS. 16 and 17 involves an example in a case in which each of the first and second multiple mirror systems 80A and 80B includes five mirrors. However, the first and second multiple mirror systems 80A and 80B are not limited thereto. Each of the first and second multiple mirror systems 80A and 80B may include more mirrors. For example, each of the first and second multiple mirror systems 80A and 80B may include 100 mirrors. In a case in which each of the first and second multiple mirror systems 80A and 80B include 100 mirrors, the pulse width may be increased to 100² times, for example, 2 ns.

Further, description of the foregoing embodiment in FIGS. 16 and 17 involves an example in which each of the mirrors in the first and second multiple mirror systems 80A and 80B has a quadrangular prism shape. However, the shape of each of the mirrors is not limited thereto, and a single substrate may be processed. For example, in each of the first and second multiple mirror systems 80A and 80B, a plurality of mirrors may be formed in a single substrate, and the reflection surfaces 81A and 81B may be coated with a high reflection film.

Furthermore, the embodiment is not limited to a case in which the pulsed laser light beam 30 obliquely enters each of the first and second multiple mirror systems 80A and 80B, and the pulsed laser light beam 30 may enter each of the first and second multiple mirror systems 80A and 80B at the incident angle γ close to 0°. In this case, the reflection surfaces 81A and 81B may be preferably coated with a multilayer film of Mo and Si or a multilayer film such as a multilayer film of CaB₆ and BaB₆ as a high reflection film.

In addition, the incident angle γ is not limited to 80°, and may be in the following range, for example. In order to improve durability of the reflection film of the reflection surfaces 81A and 81B, the pulsed laser light beam 30 may enter as obliquely as possible.

72°≦γ≦90°

### 7. Fifth Embodiment (Embodiment of Exposure Apparatus Provided with Illumination Optical System Including Multiple Mirror System)

Next, description is given of a fifth embodiment of the present disclosure with reference to FIG. 18 and other drawings. Note that substantially same components as the components of the EUV light source system, the exposure apparatus, and other systems and apparatuses according to the foregoing first to fourth embodiments are denoted by same reference numerals, and redundant description thereof is omitted.

### 7.1 Configuration

Description of the foregoing respective embodiments involves a configuration example in which the delaying optical system 40 is provided in the optical path between the free electron laser apparatus 3 and the exposure apparatus 2; however, the delaying optical system 40 may be provided in the exposure apparatus 2.

For example, like an exposure apparatus 2A illustrated in FIG. 18, the multiple mirror system 70 serving as the delaying optical system 40 may be included in an illumination optical system 21A in place of the secondary light source formation-use multiple concave mirror 25. Note that the EUV light source system 101 similar to the configuration example in FIG. 1 may be provided previous to the exposure apparatus 2A in FIG. 18.

The configuration of the multiple mirror system 70 may be substantially similar to the foregoing configuration illustrated in FIG. 12. Moreover, the shape of each of the reflection surfaces 71 of the multiple mirror system 70 may be the concave reflection surface 73 substantially similar to the configuration illustrated in the bottom section of FIG. 13. Moreover, the shape of each of the reflection surfaces 71 of the multiple mirror system 70 may be the convex reflection surface 74 substantially similar to the configuration illustrated in the bottom section of FIG. 14. In this case, focus positions of the mirrors in the multiple mirror system 70 may be located in a substantially the same plane. The optical path difference δL of reflected light beams by the respective mirrors and the pulse width ΔD of the pulsed laser light beam 30 outputted from the free electron laser apparatus 3 may satisfy the foregoing relationship represented by the expression (7).

### 7.2 Operation

In the exposure apparatus 2A, the reflected light beams by the respective mirrors of the multiple mirror system 70 may be delayed by the optical path difference SL, and a secondary light source may be formed. The secondary light source may generate illumination light with which the mask 35 is illuminated through Koehler illumination. Each light source of the secondary light source has an optical path difference by δL, which makes it possible to suppress generation of a speckle in illumination light.

### 7.3 Effect

According to the fifth embodiment, the optical path difference δL of the reflected light beams by the respective mirrors in the multiple mirror system 70 of the illumination optical system 21A is caused to increase the pulse width of the pulsed laser light beam 30 to be applied onto the mask 22 and to suppress generation of a speckle.

### 7.4 Modification Examples

FIGS. 19 to 21 each illustrate an example of a circular concave multiple mirror system 90 as another configuration example of the multiple mirror system 70 applied to the illumination optical system 21A. The circular concave multiple mirror system 90 may include a plurality of circular concave mirrors 91. Each of the circular concave mirrors 91 may include a concave reflection surface 92.

Note that FIG. 19 illustrates a top view of the circular concave multiple mirror system 90. FIG. 20 is a perspective view of the circular concave mirrors 91, and schematically illustrates a state of reflection of a light beam by each of the circular concave mirrors 91. FIG. 21 is a side view of the circular concave mirrors 91, and schematically illustrates a cross-sectional shape of each of the concave reflection surfaces 92 of the circular concave mirrors 91.

The circular concave mirrors 91 may be provided to allow a difference d between adjacent two of the concave reflection surfaces 92 to satisfy the foregoing expression (8), as illustrated in FIG. 21.

### 10. Et Cetera

The foregoing description is intended to be merely illustrative rather than limiting. It should therefore be appreciated that variations may be made in example embodiments of the present disclosure by persons skilled in the art without departing from the scope as defined by the appended claims.

The terms used throughout the specification and the appended claims are to be construed as “open-ended” terms. For example, the term “include” and its grammatical variants are intended to be non-limiting, such that recitation of items in a list is not to the exclusion of other like items that can be substituted or added to the listed items. The term “have” and its grammatical variants are intended to be non-limiting, such that recitation of items in a list is not to the exclusion of other like items that can be substituted or added to the listed items. Also, the singular forms “a”, “an”, and “the” used in the specification and the appended claims include plural references unless expressly and unequivocally limited to one referent.

What is claimed is:

1. A light source system, comprising:
a free electron laser apparatus including an undulator, and configured to output a pulsed laser light beam toward an exposure apparatus;
a light concentrating mirror configured to concentrate the pulsed laser light beam to enter the exposure apparatus; and
a delaying optical system provided in an optical path between the undulator and the light concentrating mirror, and configured to delay the pulsed laser light beam to allow an amount of delay of the pulsed laser light beam to be varied depending on a position in a beam cross-section of the pulsed laser light beam.

2. The light source system according to claim 1, wherein the delaying optical system spatially divides the pulsed laser light beam into a plurality of segments in the beam cross-section to vary the amount of delay for each of the segments.

3. The light source system according to claim 1, wherein a pulse width of the pulsed laser light beam that enters the delaying optical system is in a range from 0.1 ps to 0.2 ps both inclusive.

4. The light source system according to claim 1, wherein the delaying optical system provides the pulsed laser light beam with an optical path difference ΔL depending on the position in the beam cross-section to delay the pulsed laser light beam, the optical path difference ΔL falling within a range of 0.031 (m)≦ΔL<1.146 (m).

5. The light source system according to claim 1, wherein the delaying optical system includes at least one grating configured to diffract the pulsed laser light beam to generate a diffracted light beam, and outputs the diffracted light beam toward the exposure apparatus.

6. The light source system according to claim 1, wherein
the delaying optical system includes a first grating and a second grating, the first grating being configured to diffract the pulsed laser light beam to generate a first diffracted light beam, and the second grating being configured to diffract the first diffracted light beam to generate a second diffracted light beam, and
the delaying optical system outputs the second diffracted light beam toward the exposure apparatus.

7. The light source system according to claim 6, wherein
the first grating includes a first dispersion surface where the pulsed laser light beam enters,
the second grating includes a second dispersion surface where the first diffracted light beam enters, and
the first grating and the second grating are disposed substantially orthogonal to each other to allow the first dispersion surface and the second dispersion surface to be substantially orthogonal to each other.

8. The light source system according to claim 5, wherein the grating is a blazed grating provided with grooves disposed at a predetermined interval.

9. The light source system according to claim 8, wherein a shape of each of the grooves of the grating is one of a sinusoidal wave shape, a rectangular wave shape, and a triangular wave shape.

10. The light source system according to claim 1, wherein the delaying optical system includes at least one multiple mirror system having a plurality of reflection surfaces, and reflects the pulsed laser light beam by the reflection surfaces to generate a plurality of reflected light beams having an optical path difference with respect to one another.

11. The light source system according to claim 10, wherein the multiple mirror system satisfies the following relationship:
δL≧c·ΔD
where δL is the optical path difference between the reflected light beams, ΔD is a pulse width of the pulsed laser light beam, and c is light velocity.

12. The light source system according to claim 10, wherein a shape of each of the reflection surfaces is one of a flat shape, a concave shape, and a convex shape.

13. A beam transmission system, comprising
a delaying optical system provided in an optical path between an exposure apparatus and a free electron laser apparatus configured to output a pulsed laser light beam toward the exposure apparatus, the delaying optical system configured to delay the pulsed laser light beam to allow an amount of delay of the pulsed laser light beam to be varied depending on a position in a beam cross-section of the pulsed laser light beam, and thereafter concentrate the pulsed laser light beam.
